(19) United States
(12) Patent Application Publication
(10) Pub. No.: US 2006/0043968 A1
(43) Pub. Date: Mar. 2, 2006

(54) Distributed electromagnetic field analyzing apparatus and method of divided electromagnetic field analysis with electromagnetic field analysis calculations divided and allotted to a plurality of computers

(75) Inventor: Tatsuroh Kiso, Tenri-shi (JP)

Correspondence Address: EDWARDS & ANGELL, LLP, P.O. BOX 55874, BOSTON, MA, 02205, US

(73) Assignee: Sharp Kabushiki Kaisha, Osaka (JP)

(21) Appl. No.: 11/218,881

(22) Filed: Sep. 1, 2005

(30) Foreign Application Priority Data
Sep. 2, 2004 (JP) 2004-255627 (P)

(51) Int. Cl. G01N 27/72; G01R 33/00

(52) U.S. Cl. 324/227

(57) ABSTRACT

A distributed process control unit divides, in time and space, a main problem of finding a full time response of an analytic region into a plurality of sub-problems, allots the sub-problems to those of a plurality of calculating units which are capable of calculating a new sub-problem, to have the units perform analysis. Therefore, even when computational capacity or the like of calculating units should vary, analysis can be performed in accordance with the computational capacity of the overall system.

This nonprovisional application is based on Japanese Patent Application No. 2004-255627 filed with the Japan Patent Office on Sep. 2, 2004, the entire contents of which are hereby incorporated by reference.

### BACKGROUND OF THE INVENTION

1. Field of the Invention

The present invention relates to a technique for performing electromagnetic field analysis using a plurality of computers and, more specifically, to a distributed electromagnetic field analyzing apparatus dividing calculations for electromagnetic field analysis and allocating the same to a plurality of computers, and to a method of divided electromagnetic field analysis performing electromagnetic field analysis in a divided manner.

2. Description of the Background Art

Recently, improved speed of processing of computers has lead to various techniques to have a computer analyze an electromagnetic field of an analytic region. One such technique includes FDTD method (Finite Difference Time Domain Method), in which Maxwell's equation is differentiated in time and space, electromagnetic field of the analytic space is updated with time using leap frog algorithm, and a time response of the output point is obtained.

In electromagnetic field analysis by the FDTD method, the analytic region is divided by a mesh and unknown electromagnetic field is arranged at each mesh point. Here, a so called Yee mesh is used, in which unknown electric field and unknown magnetic field are arranged on grids shifted by half the grid width from each other. Here, each unknown electric field has six adjacent unknown magnetic fields in a three-dimensional case and four adjacent unknown magnetic fields in a two-dimensional case. Similarly, an unknown magnetic field has the same number of adjacent unknown electric fields.

The FDTD method is a method of analysis based on calculus of finite differences, in which relation acting between unknown electric and magnetic fields and adjacent unknown magnetic and electric fields is derived from Maxwell's equation based on electromagnetics, and unknown electric and magnetic fields are updated in every unit time step, to find the whole behavior of the electromagnetic field. In this method of analysis, the electric field is updated in a certain time step, the magnetic field is updated after ½ time step, and the electric field is updated again after 1 time step, and in this manner, the electric field and the magnetic field are calculated alternately.

In a parallel electromagnetic field analyzing system using the FDTD method as such, m computers are used, the analytic region is divided into m blocks, and calculations are performed in parallel by the computers corresponding to respective blocks. Here, an overlap region of one layer is provided at a boundary of the blocks, and information of electromagnetic field in the overlap region is exchanged between computers in charge of adjacent blocks, in every one time step. Related techniques are disclosed in Japanese Patent Laying Open Nos. 2003-223426 and 2004-054642.

In an information processing apparatus disclosed in Japanese Patent Laying-Open No. 2003-223426, first and second personal computers calculate electric field intensity at a prescribed computational time point of an overlap region of which electric or magnetic field is to be analyzed. The first personal computer transmits the electric field intensity of the overlap region to the second personal computer. In parallel with this transmission, the first personal computer calculates electric field intensity and magnetic field intensity at a computational time point of the divided region excluding the overlap region.

In a circuit analysis system disclosed in Japanese Patent Laying-Open No. 2004-054642, the circuit analysis system is formed of first to fifth computers connected through a network, the first and second computers perform electromagnetic field analysis in accordance with the FDTD method, and the fourth and fifth computers simulate. The region as the object of analysis is divided into a plurality of sub-regions and overlap regions between these sub-regions, electromagnetic field analysis is performed in parallel by the first and second computers, and the fourth and fifth computers simulate in parallel equivalent circuit network in each sub-region. The third computer controls synchronization between each of the computers.

A problem of finding electromagnetic field behavior of the analytic region as a whole from the initial state to a time point satisfying an end condition will be referred to as a main problem. An electromagnetic field analyzing apparatus performing an analysis in time domain by, for example, FDTD method, can be regarded as an apparatus that solves a given main problem. The electromagnetic field analyzing apparatus using one computer described above performs all the calculations necessary to solve the main problem by one computer.

Problems resulting from division of the main problem along the spatial direction will be referred to as sub-problems. Techniques disclosed in Japanese Patent Laying-Open Nos. 2003-223426 and 2004-054642 are for performing parallel/distributed processing by allotting one sub-problem to one computer. In such an electromagnetic field analyzing apparatus, the computers must be connected to each other by a high-speed network with small delay.

Further, in order that all the computers finish calculations in approximately the same time period, at the start of analysis, blocks corresponding to the capacity of respective computers are allotted to disperse computational burden. Therefore, the system is weak against variation in computational capacity of each computer during calculation, and further, the computers must be exclusively used for the system operation during calculation. In addition, the system does not allow increase/decrease of computers during calculation for analysis.

Further, it is necessary twice in one time step, that is, before the calculation of electric field and before the calculation of magnetic field, to establish synchronization of electromagnetic field information between each of the computers, which undesirably degrades performance because of wait time for communication. In the method of improved FDTD calculation disclosed in Japanese Patent Laying-Open No. 2003-223426, calculation is made possible with the necessary time of synchronization of information in every time step reduced to one. This method, however, is still on the premise that a network with relatively small delay is used, and therefore, it is difficult to employ this method in a general network such as the Internet or intranet.

### SUMMARY OF THE INVENTION

An object of the present invention is to provide a distributed electromagnetic field analyzing apparatus, capable of performing analyzing process matching the computational capability of the system as a whole.

Another object is to provide a method of divided electromagnetic field analysis capable of performing calculations of sub-problems over time steps, in an asynchronous manner.

According to an aspect, the present invention provides a distributed electromagnetic field analyzing apparatus, causing a plurality of computers connected to a network to perform electromagnetic field analysis in accordance with calculus of finite differences, including: a plurality of calculating units for performing electromagnetic field analysis; and a distributed process control unit dividing, in time and space, a main problem of finding a full time response of an analytic region into a plurality of sub-problems, allotting the sub-problems to the plurality of calculating units respectively to have the units perform analysis.

Therefore, even when the computational capability of the calculating unit varies, analysis according to the computational capability of the whole system can be performed.

Preferably, the distributed process control unit includes a dividing unit dividing the analytic region of the main problem into a plurality of blocks, an extracting unit extracting, from the plurality of calculating units, one that is available for calculating a new sub-problem, a processing unit dividing the plurality of blocks divided by the dividing unit in every prescribed number of steps to generate a plurality of sub-problems, and allotting a sub-problem that can be calculated to the calculating unit extracted by the extracting unit, and a transmitting unit transmitting a calculation instruction of the sub-problem allotted by the processing unit to the calculating unit.

Therefore, sub-problems of the same block can dynamically be moved to a different calculating unit.

More preferably, the processing unit has a counter indicating the number of sub-problems of which calculation has been finished for every block, and manages state of progress of calculation based on the value of the counter.

Therefore, progress of calculation of the sub-problem can appropriately be managed.

More preferably, the processing unit extracts a sub-problem that can be calculated, based on state of progress of sub-problem calculation and correlation among the plurality of blocks.

Therefore, sub-problems can more easily be allotted.

Preferably, the processing unit allots sub-problems continuous in time in one block to one same calculating unit.

Therefore, necessary amount of communication and wait time for communication can be reduced.

Preferably, where the prescribed number of steps is n that is not smaller than 2, in calculating the allotted sub-problem, the calculating unit calculates an electromagnetic field of a block based on electromagnetic field information in the block corresponding to the sub-problem and on electromagnetic field information of n layers of overlap regions in the vicinity of the block.

Therefore, calculations of sub-problems over n time steps can be performed in asynchronous manner.

More preferably, the calculating unit calculates electromagnetic field of up to n layers in the vicinity of the block in a first time step, calculates electromagnetic field of up to n−1 layers in the vicinity of the block in a second time step, and repeats these processes to narrow the region of which electromagnetic field is to be calculated, and calculates electromagnetic field only in the block in the n-th step.

Therefore, calculations of sub-problems over n time steps can be performed in asynchronous manner.

According to another aspect, the present invention provides a method of divided electromagnetic field analysis, dividing an analytic region into a plurality of blocks and performing electromagnetic field calculation of the divided blocks in prescribed time steps, including the steps of: where the prescribed number of steps is n that is not smaller than 2, prior to calculation of electromagnetic field in a block, obtaining electromagnetic field information of the block and electromagnetic field information of n layers of overlap regions in the vicinity of the block; and calculating the electromagnetic field of the block based on the obtained electromagnetic field information.

Preferably, the step of calculating electromagnetic field includes the steps of calculating electromagnetic field of up to n layers in the vicinity of the block in a first time step, calculating electromagnetic field of up to n−1 layers in the vicinity of the block in a second time step, repeating these processes to narrow the region of which electromagnetic field is to be calculated, and calculating electromagnetic field only in the block in the n-th step.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram representing an exemplary configuration of a distributed electromagnetic field analyzing apparatus in accordance with an embodiment of the present invention.

FIG. 2 is a block diagram representing an exemplary configuration of a distributed process control unit 1 shown in FIG. 1.

FIG. 3 is a block diagram representing a functional configuration of distributed process control unit 1.

FIG. 4 is a flow chart representing steps of processing by distributed process control unit 1.

FIG. 5 shows an example of block division of an analytic region.

FIG. 6 shows an example of a block not neighboring the outside of the analytic region.

FIG. 7 shows an example of a block neighboring the outside of the analytic region.

FIG. 8 represents correlation between i-th sub-problem and i+1th sub-problem.

FIG. 9 is a block diagram representing a functional configuration of computing units 2-1 to 2-m.

FIG. 10 is a flow chart representing steps of processing by computing units 2-1 to 2-m.

FIG. 11 is a flow chart representing steps of processing by a calculation result output unit 22.

FIG. 12 represents electromagnetic information in a block and electromagnetic information of block-n-vicinity when n=1.

FIG. 13 represents electromagnetic information in a block and electromagnetic information of block-n-vicinity when n=2.

FIG. 14 represents electromagnetic information in a block and electromagnetic information of block-n-vicinity when n=3.

FIG. 15 represents the scope of electromagnetic field calculated in a loop S33 to S37 (loop counter j=1) of FIG. 10 by calculating units 2-1 to 2-m, when n=3.

FIG. 16 represents the scope of electromagnetic field calculated in a loop S33 to S37 (loop counter j=1) of FIG. 10 by calculating units 2-1 to 2-m, when n=3.

FIG. 17 represents the scope of electromagnetic field calculated in a loop S33 to S37 (loop counter j=2) of FIG. 10 by calculating units 2-1 to 2-m, when n=3.

FIG. 18 represents the scope of electromagnetic field calculated in a loop S33 to S37 (loop counter j=2) of FIG. 10 by calculating units 2-1 to 2-m, when n=3.

FIG. 19 represents the scope of electromagnetic field calculated in a loop S33 to S37 (loop counter j=3) of FIG. 10 by calculating units 2-1 to 2-m, when n=3.

FIG. 20 represents the scope of electromagnetic field calculated in a loop S33 to S37 (loop counter j=3) of FIG. 10 by calculating units 2-1 to 2-m, when n=3.

### DESCRIPTION OF THE PREFERRED EMBODIMENTS

Given a problem of finding an electromagnetic field in an analytic region until a certain end condition is satisfied, the parallel/distributed electromagnetic field analyzing apparatus of the present embodiment (hereinafter also simply referred to as a distributed electromagnetic field analyzing apparatus) calculates the result of the problem, from initial electromagnetic field distribution of the analytic region, positional information and electromagnetic characteristic information of all the objects existing in the analytic region, and boundary condition at the boundary of analytic region. In the following, the problem of finding the electromagnetic field until the end condition is satisfied will be referred to as a main problem. The distributed electromagnetic field analyzing apparatus of the present embodiment divides the main problem into a plurality of sub-problems in some way or other, which sub-problems are allotted to a plurality of calculating units to be processed in parallel/distributed manner.

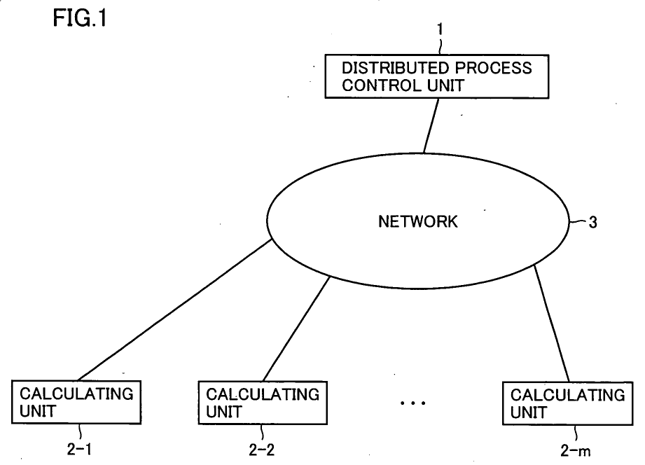

FIG. 1 is a block diagram representing an exemplary configuration of a distributed electromagnetic field analyzing apparatus in accordance with the present embodiment. The distributed electromagnetic field analyzing apparatus includes a distributed process control unit 1 for controlling the distributed electromagnetic field analyzing apparatus as a whole, a plurality of calculating units 2-1 to 2-m analyzing each of the sub-problems, and a network 3 connecting distributed process control unit 1 and calculating units 2-1 to 2-m.

Distributed process control unit 1 divides the analytic region of a given main problem into blocks, and further divides the blocks into the number n of time steps (n>1) to generate sub-problems. Further, distributed process control unit 1 manages sub-problem progress information, information of calculated sub-problem electromagnetic field itself, information representing location of the information of calculated sub-problem electromagnetic field, and state of use of calculating units 2-1 to 2-m, and determines sub-problems that can be calculated next, based on these pieces of information. These sub-problems are allotted to respective calculating units 2-1 to 2-m and transmitted, together with information necessary for calculating the sub-problems, to calculating units 2-1 to 2-m through network 3, as instruction information.

Based on the instruction information received from network 3 from distributed process control unit 1, calculating units 2-1 to 2-m request other calculating unit or units for information necessary to calculate the sub-problems, through network 3, calculate the sub-problems, and every time a state transition occurs at the end of calculation or the like, transmit new state to distributed process control unit 1. Further, the calculating unit transmits, upon request from other calculating unit or units, electromagnetic field information of the result of calculation of the sub-problem or part of the electromagnetic field information held therein to distributed process control unit 1 or to other calculating unit or units, through network 3.

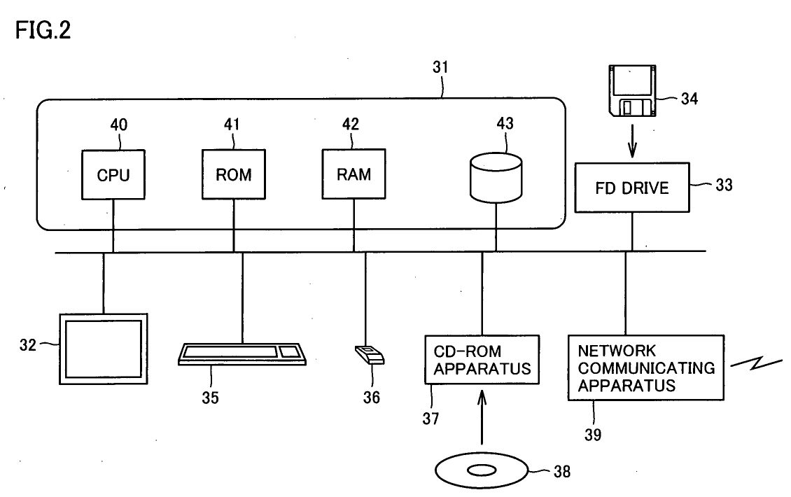

FIG. 2 is a block diagram representing an exemplary configuration of distributed process control unit 1 shown in FIG. 1. It is noted that calculating units 2-1 to 2-m also have the same configuration.

Distributed process control unit 1 includes a computer body 31, a display apparatus 32, an FD drive 33 to which an FD (Flexible Disk) 34 is mounted, a keyboard 35, a mouse 36, a CD-ROM apparatus 37 to which a CD-ROM (Compact Disk-Read Only Memory) 38 is mounted, and a network communication apparatus 39. A distributed process control program is supplied by a recording medium such as FD 34 or CD-ROM 38. When the distributed process control program is executed by computer body 31, generation and allocation of sub-problems and the like described above are performed. Alternatively, the distributed control program may be supplied to computer body 31 through a communication network, from another computer.

Computer body 31 includes a CPU 40, a ROM (Read Only Memory) 41, a RAM (Random Access Memory) 42 and a hard disk 43. CPU 40 processes while inputting/outputting data from and to display apparatus 32, FD drive 33, keyboard 35, mouse 36, CD-ROM apparatus 37, network communication apparatus 39, ROM 41, RAM 42 or hard disk 43. The distributed process control program recorded on FD 34 or CD-ROM 38 is stored by CPU 40 through FD drive 33 or CD-ROM apparatus 37 in hard disk 43. CPU 40 appropriately loads the distributed process control program from hard disk 43 to RAM 42 and executes the same, whereby generation and allocation of sub-problems and the like described above are performed.

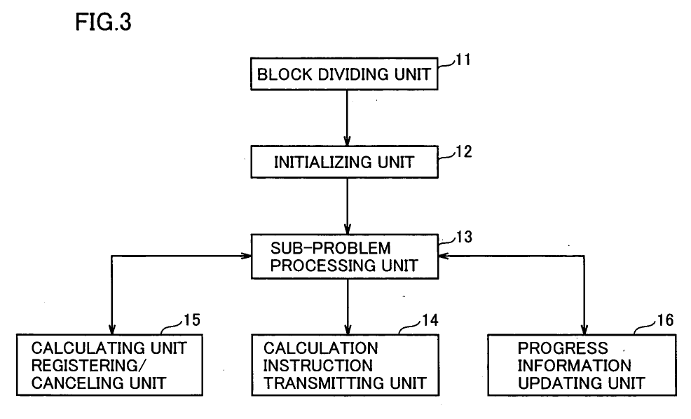

FIG. 3 is a block diagram representing a functional configuration of distributed process control unit 1. Distributed process control unit 1 includes: a block dividing unit 11 dividing an analytic region into a plurality of rectangular blocks; an initializing unit 12 initializing electromagnetic field analysis; a sub-problem processing unit 13 determining whether a sub-problem can be calculated or not, and allocating a sub-problem that can be calculated to any of the plurality of free calculating units; a calculation instruction transmitting unit 14 transmitting a calculation instruction of a sub-problem; a calculation unit registering/canceling unit 15 registering/canceling a calculating unit; and a progress information updating unit 16 updating progress information of sub-problem calculation.

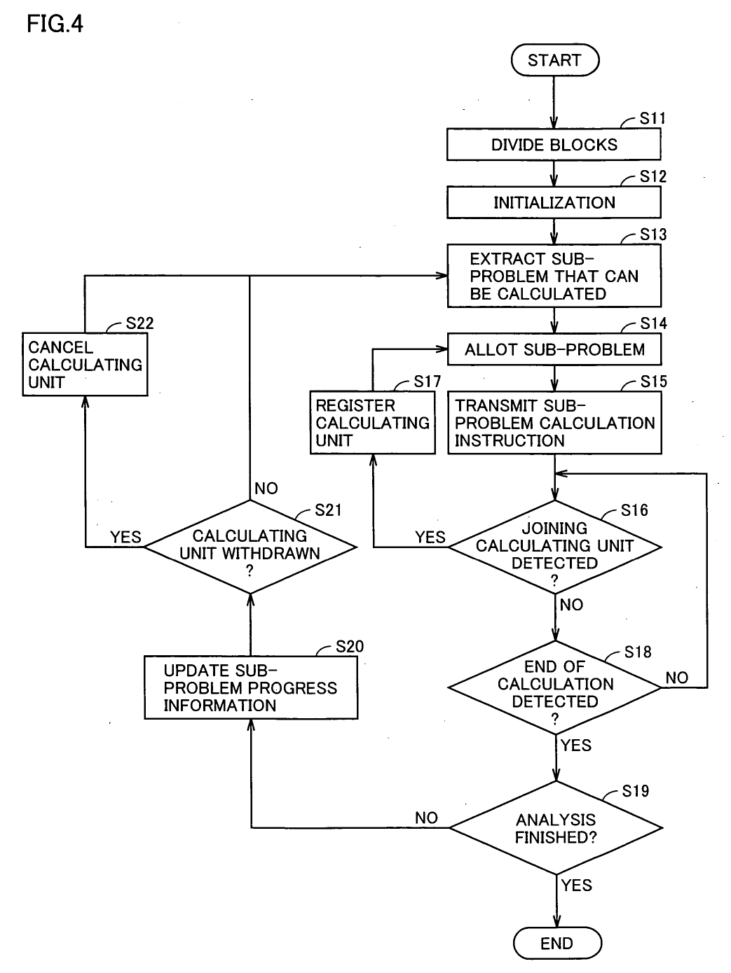

FIG. 4 is a flow chart representing the steps of processing performed by distributed process control unit 1. In the following, electromagnetic field analysis in two-dimensional case will be described. Process can be performed in the similar manner in three-dimensional electromagnetic field analysis. First, block dividing unit 11 divides a given analytic region into a plurality of rectangular blocks (S11).

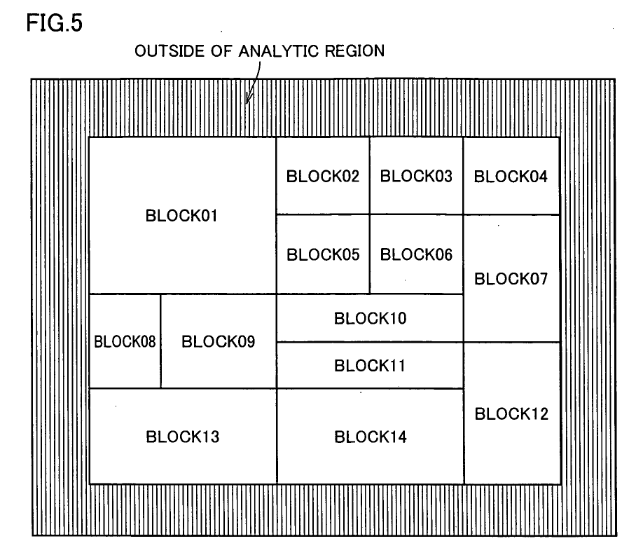

FIG. 5 shows an example of block division of the analytic region. Referring to FIG. 5, the analytic region is divided into fourteen blocks 01 to 14. As to the method of division here, all the blocks may have one same size or different size. When an absorbing boundary layer is provided at the boundary with the outside of the analytic region, the process proceeds assuming that the absorbing boundary layer is included in an adjacent block.

Next, initializing unit 12 initializes electromagnetic field analysis (S12). Specifically, each block obtained by block division is divided in every time step number n along the time axis, to generate first sub-problems, which are added to a group of sub-problems to be calculated. Further, sub-problem calculation end counter of each block as the sub-problem progress information is initialized to zero.

In the following description, a time unit is referred to as one time step, a sub-problem for calculating an electric field from time point (i−1)*n+1 to time point i*n and calculating a magnetic field from time point (i−1)*n+ 3/2 to time point 1*n+½ of block number b will be represented as sub-problem (b, i), and the sub-problem (b, i) is referred to as the i-th sub-problem of block b. Further, the electromagnetic field information of block b at time point i*n after calculation of sub-problem (b, i) will be referred to as the result of calculation of sub-problem (b, i), and initial state of electromagnetic field in each block will be referred to as the result of calculation of 0-th sub-problem.

Further, initializing unit 12 inquires about the state of each of calculating units 2-1 to 2-m through network 3, and collects information of calculating units that can actually be used, to initialize the calculating unit management information. The calculating unit management information manages at least a busy flag indicating whether the unit is being used (busy) or not, in correspondence to a calculating unit 1D. Further, initializing unit 12 resets all the busy flags. Further, computational capacity of each of calculating units 2-1 to 2-m, network distance between each of calculating units 2-1 to 2-m and the like may also be managed and utilized for sub-problem allocation.

Next, sub-problem processing unit 13 determines whether each sub-problem in the group of sub-problems to be calculated can be calculated or not (S13). Here, a sub-problem (b, i+1) can be calculated only when sub-problem (b, i) has already been calculated and i-th sub-problem of the blocks including n-vicinity of block b has already been calculated.

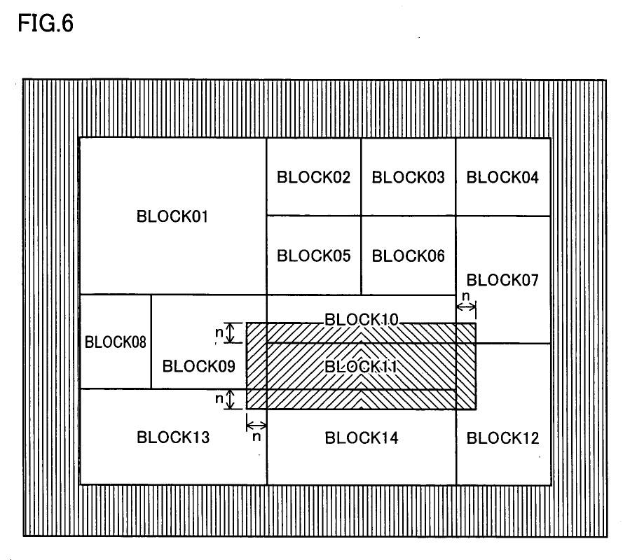

FIG. 6 shows an example of a block not neighboring the outside of the analytic region. As can be seen from FIG. 6, the i+1-th sub-problem of block 11 not neighboring the outside of analytic region can be calculated when sub-problems (11, i), (07, i), (09, i), (10, i), (12, i), (13, i) and (14, i) have already been calculated.

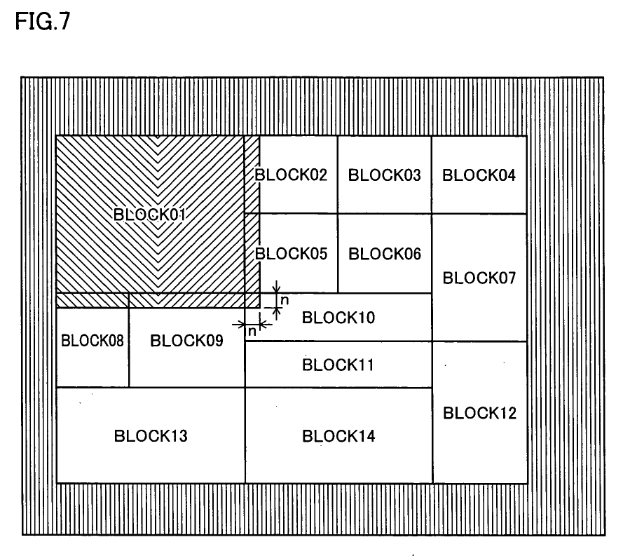

FIG. 7 shows an example of a block neighboring the outside of the analytic region. As can be seen from FIG. 7, the i+1-th sub-problem of block 01 neighboring the outside of analytic region can be calculated when sub-problems (01, i), (02, i), (05, i), (08, i), (09, i) and (10, i) have already been calculated.

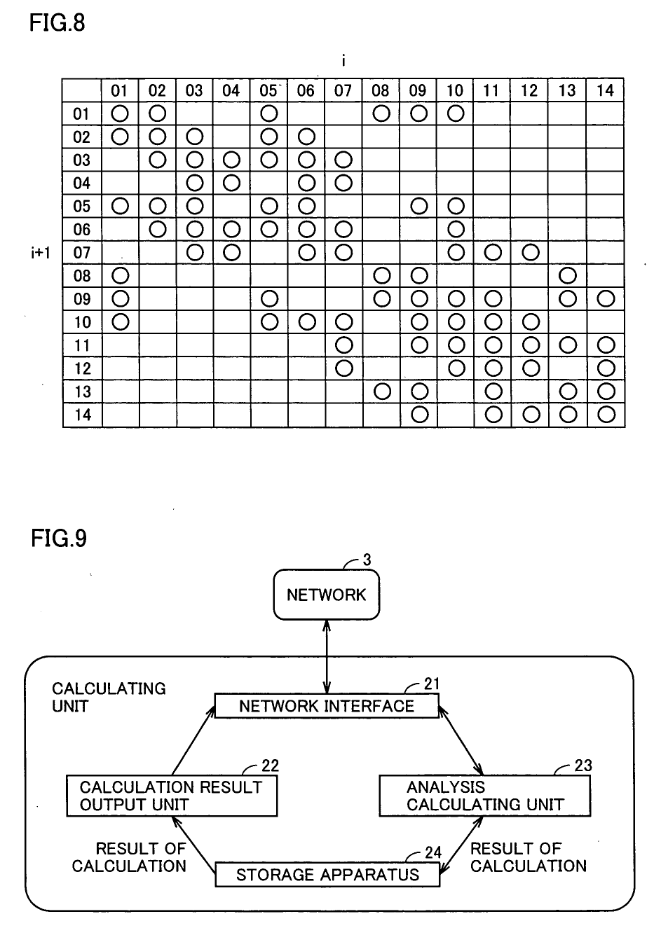

FIG. 8 represents correlation between the i-th sub-problem and the i+1-th sub-problem. This table represents how the i+1-th sub-problem of each block depends on which i-th sub-problem of which block, when the analytic region is divided into blocks as shown in FIG. 5. Sub-problem processing unit 13 can determine whether each sub-problem can be calculated or not, by making a reference to this table and to the sub-problem progress information.

Next, sub-problem processing unit 13 specifies a free calculating unit based on the busy flag of calculating unit managing information, and allots the extracted sub-problem that can be calculated (S14). Then, the busy flag of the calculating unit management information corresponding to the calculating unit to which allocation has been determined, is set. Here, in determining to which of the plurality of free calculating units a certain sub-problem should be allotted, a simple scheme such as FIFO may be used. When a calculating unit that calculated the sub-problem immediately preceding the sub-problem that can be calculated is free, however, the sub-problem belonging to the same block should be allotted to this calculating unit, as it enables efficient allocation considering computational capacity, number of nodes, network topology, communication delay and amount of communication, whereby overall performance can be improved.

Next, calculation instruction transmitting unit 14 transmits information necessary to calculate the sub-problem, to the calculating unit to which the sub-problem is allotted (S15). When the result of calculation of the sub-problem is held by distributed process control unit 1 itself, the information is embedded directly in the instruction, and when the result is held by other calculating unit, location information of the result of calculation is embedded in the instruction. After information necessary to calculate the sub-problem is transmitted, progress information updating unit 16 deletes the corresponding sub-problem from the group of sub-problems to be calculated, registers it with a group of sub-problems being calculated, and manages the same together with the information of the calculating unit to which the sub-problem is allotted.

Next, calculating unit registering/canceling unit 15 detects a calculating unit that newly joins calculation through network 3. When a calculating unit that newly joins calculation is detected (S16, Yes), an entry is newly added to calculating unit management information and a busy flag of the entry is reset, to register the calculating unit (S17). Then, the flow returns to step S14, and the process steps thereafter are repeated.

When a calculating unit that newly joins calculation is not detected (S16, No), a process for detecting a calculation end notification by calculating units 2-1 to 2-m is performed. When end of calculation is not detected (S18, No), the flow returns to step S16, and the process steps thereafter are repeated.

When end of calculation is detected (S18, Yes), progress information updating unit 16 cancels the sub-problem corresponding to the calculating unit from the group of sub-problems being calculated, and registers the same with the group of calculated sub-problems. Further, the sub-problem calculation end counter of the block corresponding to the sub-problem is incremented by 1. At this time, as location information of the result of calculation of the sub-problem, the calculating unit to which the sub-problem has been allotted is registered. Further, the busy flag of the calculating unit management information corresponding to the calculating unit that has finished calculation is reset.

Thereafter, sub-problem processing unit 13 makes an end determination (S19), based on conditions such as termination time, convergence of incoming energy value and the like. By way of example, the end determination is made dependent on whether all sub-problems exceeding the termination time have been calculated in all the blocks or not. If “end” determination is made, (S19, Yes), the process as a whole is terminated.

If “end” determination is not made (S19, No), progress information updating unit 16 registers the sub-problem next to the block of the calculated sub-problem with the group of sub-problems to be calculated, thereby updating the sub-problem progress information (S20).

Next, calculating unit registering/canceling unit 15 determines whether withdrawal information indicating that the calculating unit will not join further calculation is included in the calculation end information from the calculating unit or not (S21). When withdrawal information is included (S21, Yes), calculating unit registering/canceling unit 15 cancels registration of the calculating unit (S22). Specifically, based on the location information of the result of sub-problem calculation, among the results of sub-problem calculation held by the calculating unit of interest, those necessary for calculating other sub-problems or port response are specified, a request for outputting the results of sub-problem calculation is transmitted to the calculating unit, with the distributed process control portion 1 designated as the destination of transfer, and the control waits for transfer of the results of sub-problem calculation. Location information of the transferred results of sub-problem calculation is set to distributed process control unit 1, and when the processes for all the corresponding results of sub-problem calculations are finished, the entry of the corresponding calculating unit in the calculating unit management information is cancelled. Then, control returns to step S13 and the following process steps are repeated.

When the withdrawal information is not included (S21, No), control returns to step S13 and the following process steps are repeated.

FIG. 9 is a block diagram showing a functional configuration of calculating units 2-1 to 2-m. Calculating units 2-1 to 2-m each include a network interface 21 connected to network 3, an analysis calculating unit 23 performing calculation of the sub-problem given by distributed process control unit 1, a storage apparatus 24 holding electromagnetic field information as the result of sub-problem calculation, and a calculation result output unit 22 reading the result of sub-problem calculation from storage apparatus 24 upon request from distributed process control unit 1 or from other calculating unit, processes the same to a required format, and transmits the same to the requested destination.

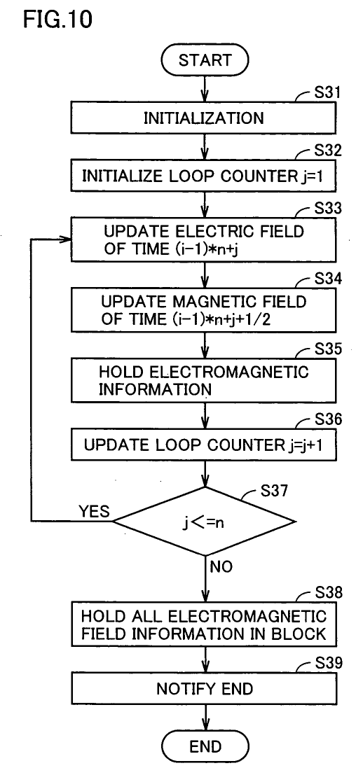

FIG. 10 is a flow chart representing steps of processing performed by calculating units 2-1 to 2-m. First, based on an instruction from distributed process control unit 1, analysis calculating unit 23 determines calculating units that hold the result of sub-problem calculation of block b and result of sub-problem calculation of adjacent blocks, transmits a request for transferring result of calculation to these calculating units, and stores the received information in RAM 42 or the like, for initialization (S31). When a calculating unit instructed by distributed process control unit 1 is holding a result of sub-problem calculation, the corresponding information is read from storage apparatus 24 provided inside the unit itself, and stored in RAM 42 or the like.

Next, analysis calculating unit 23 initializes a loop counter j to 1 (S32). Thereafter, from the magnetic field information at time point (i−1)*n+j−½ and electric field information at time point (i−1)*n+j−1, the electric field information is calculated and updated (S33). Details of the method of calculation will be described later.

Next, analysis calculating unit 23 calculates and updates magnetic field information from the electric field information at time point (i−1)*n+j and magnetic field information at time point (i−1)*n+j−½ (S34). Details of the method of calculation will be described later.

Then, analysis calculating unit 23 stores only those pieces of electromagnetic field information which are necessary to calculate port response or the like later, among all the pieces of electromagnetic information in the block (S35). When port response can be calculated by the data within the block only, the port response is calculated and stored in storage apparatus 24.

Next, analysis calculating unit 23 adds 1 to loop counter j (S36), and determines whether the count of loop counter is n or smaller (S37). When the loop counter is n or smaller (S37, YES), analysis calculating unit 23 returns to step S33 and repeats the process steps from this step. When the loop counter attains n+1 (S37, No), the control proceeds to step S38.

In step S38, analysis calculating unit 23 writes data for calculating boundary condition of external boundary neighboring block b and within the block b (such as electromagnetic field information in PML and the like) in storage apparatus 24.

Finally, analysis calculating unit 23 transmits end of calculation of sub-problems to distributed process control unit 1 through network 3 (S39), and ends processing.

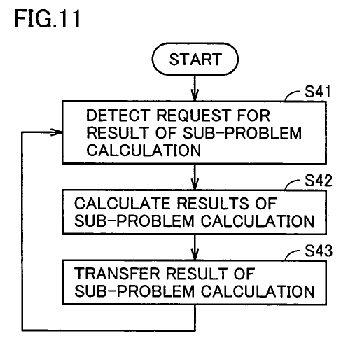

FIG. 11 is a flow chart representing the steps of processing by calculation result output unit 22. First, calculation result output unit 22 waits for a transmission request for the result of sub-problem calculation from distributed process control unit 1 or from other calculating unit, through network 3.

Receiving the transmission request for the result of sub-problem calculation, calculation result output unit 22 processes the result of sub-problem calculation held in storage apparatus 24 to a requested format (S42). The requested format may include all the data for calculating boundary condition and all electromagnetic field in sub-problems used for calculating the next sub-problem in the same block, partial electromagnetic field information used for calculation of adjacent blocks, and partial electromagnetic field information used for port response calculation. In order to reduce network load in transmitting the electromagnetic field information, compression of the requested electromagnetic field information is also performed. Other method used for sub-problem calculation includes lossless compression and lossless or lossy compression used as a format for calculating port response.

Finally, calculation result output unit 22 transfers the result of calculation to a designated destination (S43), and the control returns to step S41 and the following process steps are repeated.

The method of calculating sub-problems divided along the time direction in the distributed electromagnetic field analyzing apparatus in accordance with the present embodiment will be described. In the FDTD method, assuming that medium information is given as a constant in advance, what is necessary for calculating an unknown electric field at a certain electromagnetic mesh point at time point t in a certain time step unit are only the value of electric field at time point t−1 at the electric field mesh point and the value of magnetic field at time point t−½ at a magnetic field mesh point adjacent to that electric filed mesh point.

Specifically, the electromagnetic field information at time point t necessary for calculating the values of electric field at time point t+n and magnetic field at time point t+n+½ existing in a block b can be calculated simply from the electromagnetic field information of block b and electromagnetic field information of n layers neighboring block b (hereinafter referred to as block-n-vicinity).

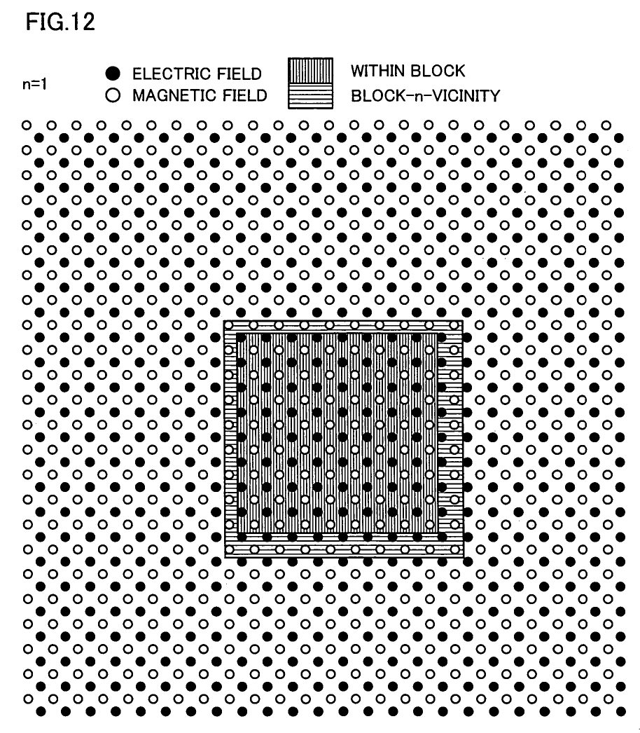

FIG. 12 shows the electromagnetic field information in the block and the electromagnetic field information of block-n-vicinity when n=1. The portion hatched with vertical lines represents the block and the portion hatched with horizontal lines represents the block-n-vicinity.

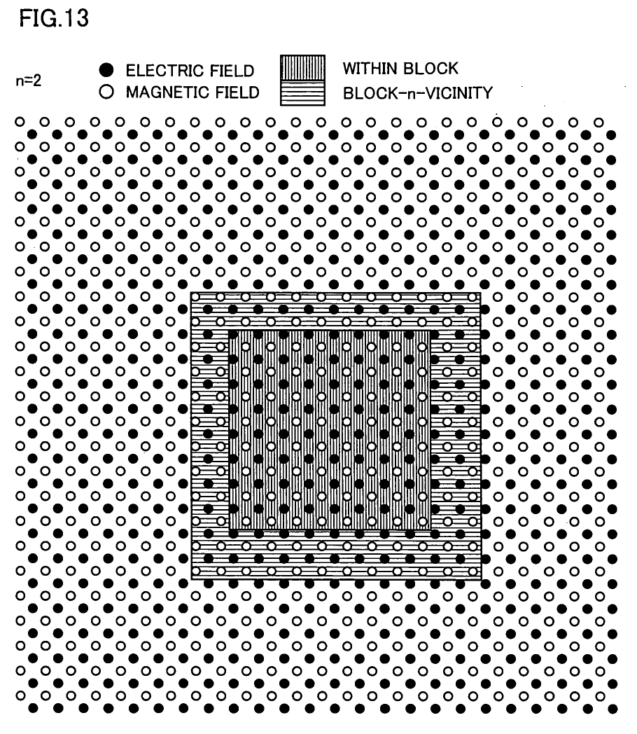

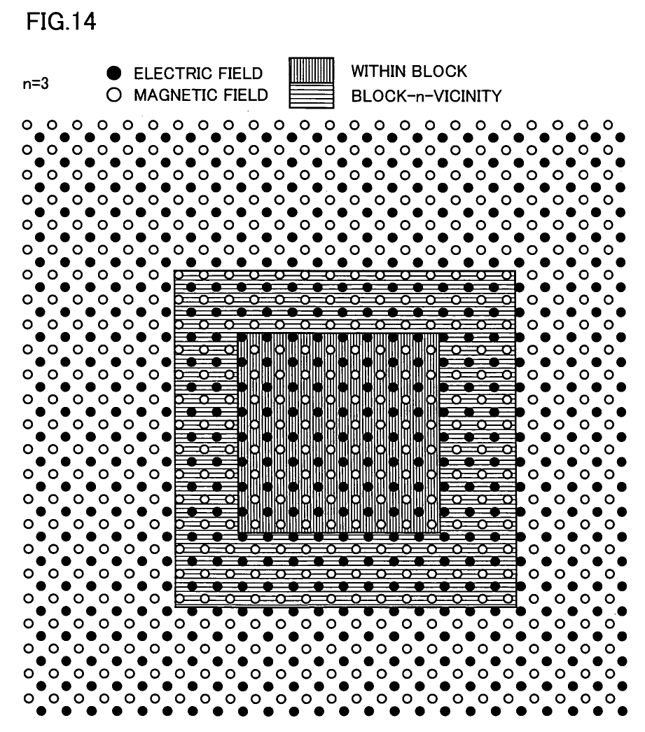

FIG. 13 shows the electromagnetic field information in the block and the electromagnetic field information of block-n-vicinity when n=2. FIG. 14 shows the electromagnetic field information in the block and the electromagnetic field information of block-n-vicinity when n=3.

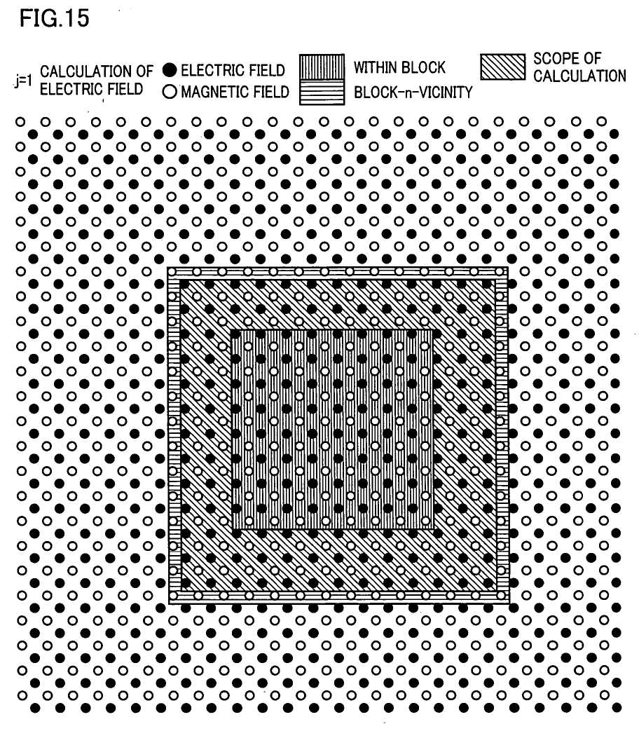

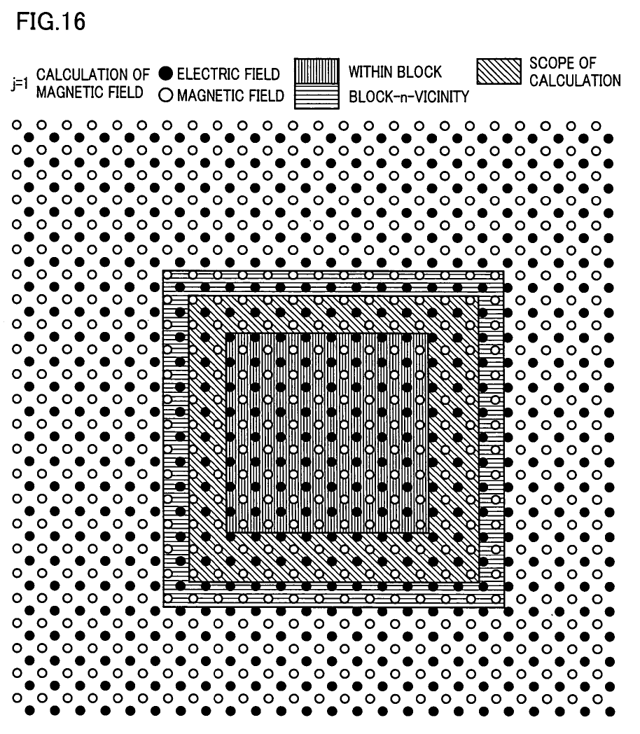

FIGS. 15 and 16 represent the scope of electromagnetic field calculated in loop S33 to S37 (loop counter j=1) shown in FIG. 10, by calculating units 2-1 to 2-m, when n=3. The scope of calculation corresponds to the block hatched by vertical lines and the portion hatched by diagonal lines.

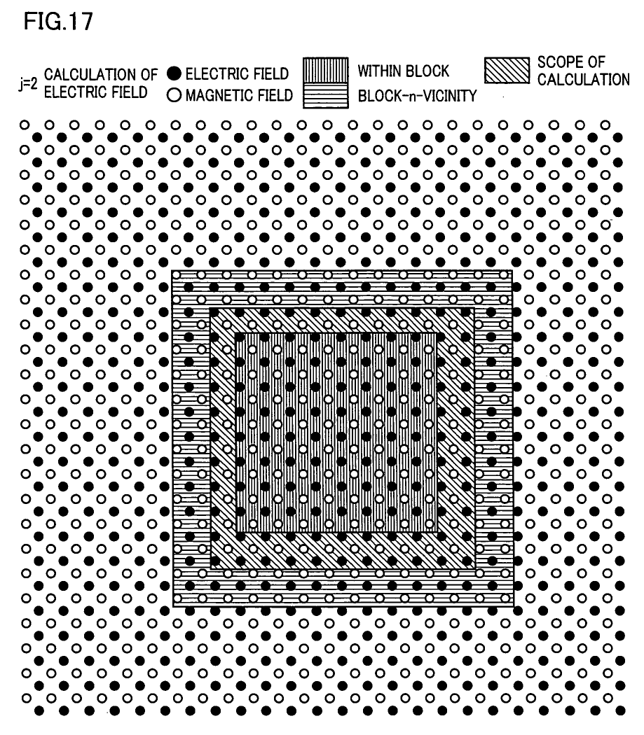

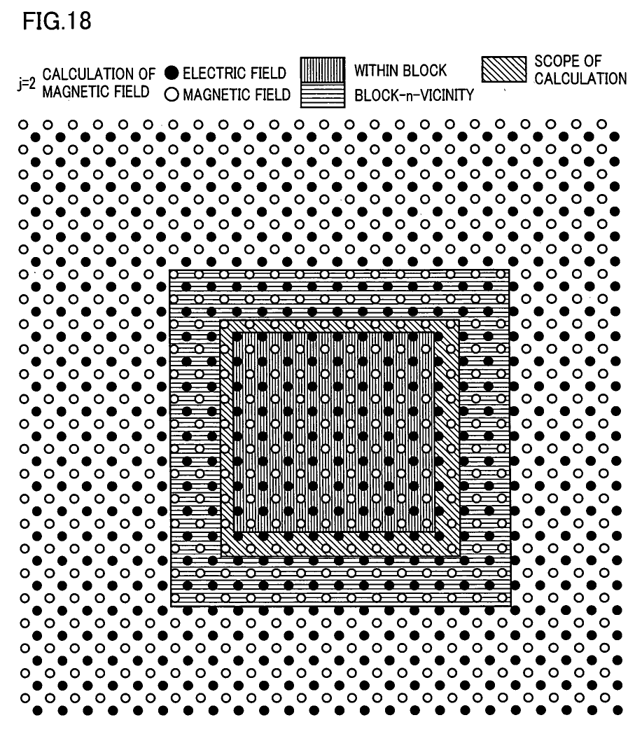

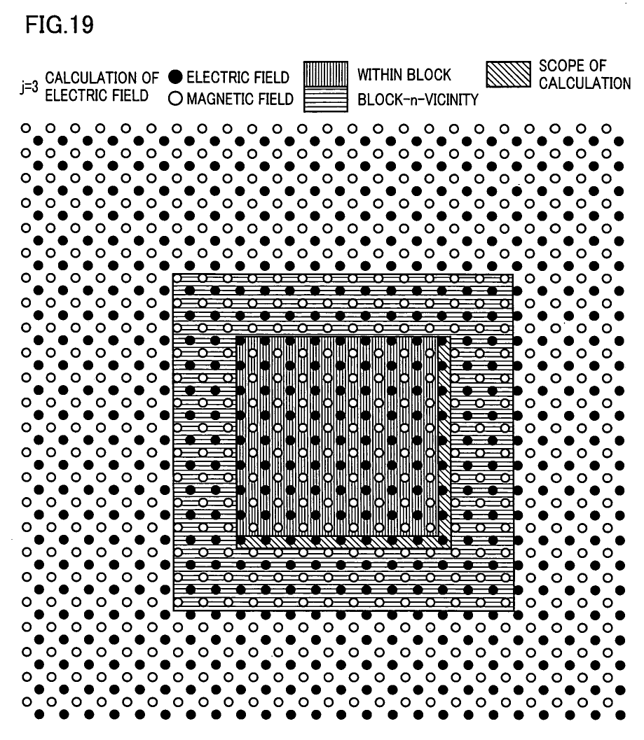

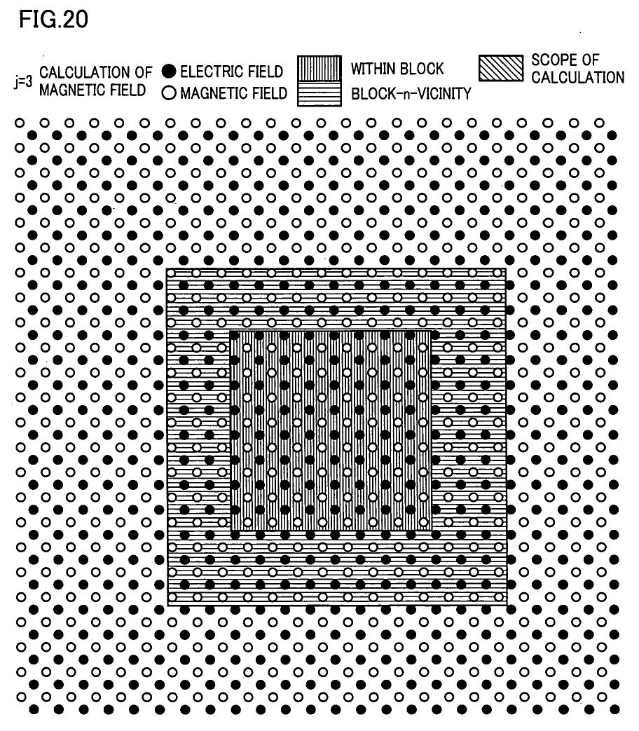

FIGS. 17 and 18 represent the scope of electromagnetic field calculated in loop S33 to S37 (loop counter j=2) shown in FIG. 10, by calculating units 2-1 to 2-m, when n=3. FIGS. 19 and 20 represent the scope of electromagnetic field calculated in loop S33 to S37 (loop counter j=3) shown in FIG. 10, by calculating units 2-1 to 2-m, when n=3.

In this manner, as the loop counter j increases, the scope of calculation is made smaller, and hence efficient calculation of electromagnetic field becomes possible.

As described above, in the distributed electromagnetic field analyzing apparatus in accordance with the present embodiment, when distributed process control unit 1 divides the main problem into sub-problems, the problem is divided not only in space but also in time, and the sub-problems are allotted to calculating units 2-1 to 2-m, respectively. Therefore, even when the number of calculating units or computational capacity that is available for the analysis in each calculating unit vary because of various factors during analysis, the process of analysis can be performed in accordance with the computational capacity of the overall system. At this time, the upper limit of the number of sub-problems that can be calculated in parallel is determined by the number of block division. Therefore, when the number of block division is set larger as compared with the number of available calculating units, computing capacity of the calculating units can efficiently be utilized.

Further, calculating units 2-1 to 2-m can calculate sub-problems over the number of time steps n (n>1) in an asynchronous manner, and therefore, it becomes possible to perform distributed electromagnetic field analysis by a group of computers connected by a general network such as in-house LAN (Local Area Network) having much delay.

Further, blocks and sub-problems can be divided independent from the configuration of calculating units, and therefore, sub-problems within the same block can dynamically be moved in accordance with the magnitude of computational burden or increase/decrease of the number of calculating units.

Further, n layers of overlap regions are provided between blocks obtained by spatially dividing the analytic region, and analysis proceeds with the calculation region narrowed one by one in every time step. Therefore, electromagnetic fields over n time steps of the block can be calculated independent of other blocks.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A distributed electromagnetic field analyzing apparatus, causing a plurality of computers connected to a network to perform electromagnetic field analysis in accordance with calculus of finite differences, comprising:
a plurality of calculating units for performing electromagnetic field analysis; and
a distributed process control unit dividing, in time and space, a main problem of finding a full time response of an analytic region into a plurality of sub-problems, and allotting the sub-problems to said plurality of calculating units respectively to have the units perform analysis.

2. The distributed electromagnetic field analyzing apparatus according to claim 1, wherein
said distributed process control unit includes
a dividing unit dividing the analytic region of the main problem into a plurality of blocks,
an extracting unit extracting, from said plurality of calculating units, one that is available for calculating a new sub-problem,
a processing unit dividing the plurality of blocks divided by said dividing unit in every prescribed number of steps to generate a plurality of sub-problems, and allotting a sub-problem that can be calculated to the calculating unit extracted by said extracting unit, and
a transmitting unit transmitting a calculation instruction of the sub-problem allotted by said processing unit to said calculating unit.

3. The distributed electromagnetic field analyzing apparatus according to claim 2, wherein
said processing unit has a counter indicating the number of sub-problems of which calculation has been finished for every block, and manages state of progress of calculation based on a value of the counter.

4. The distributed electromagnetic field analyzing apparatus according to claim 3, wherein
said processing unit extracts a sub-problem that can be calculated, based on state of progress of sub-problem calculation and correlation among the plurality of blocks.

5. The distributed electromagnetic field analyzing apparatus according to claim 2, wherein
said processing unit allots sub-problems continuous in time in one block to one same calculating unit.

6. The distributed electromagnetic field analyzing apparatus according to claim 2, wherein
where said prescribed number of steps is n that is not smaller than 2,
in calculating the allotted sub-problem, said calculating unit calculates an electromagnetic field of a block based on electromagnetic field information in the block corresponding to the sub-problem and on electromagnetic field information of n layers of overlap regions in the vicinity of the block.

7. The distributed electromagnetic field analyzing apparatus according to claim 6, wherein
said calculating unit calculates electromagnetic field of up to n layers in the vicinity of the block in a first time step, calculates electromagnetic field of up to n−1 layers in the vicinity of the block in a second time step, repeats these processes to narrow the region of which electromagnetic field is to be calculated, and calculates electromagnetic field only in the block in the n-th step.

8. A method of divided electromagnetic field analysis, dividing an analytic region into a plurality of blocks and performing electromagnetic field calculation of the divided blocks in prescribed time steps, comprising the steps of:
where said prescribed number of steps is n that is not smaller than 2,
prior to calculation of electromagnetic field in a block, obtaining electromagnetic field information of the block and electromagnetic field information of n layers of overlap regions in the vicinity of said block; and
calculating the electromagnetic field of said block based on said obtained electromagnetic field information.

9. The method of divided electromagnetic field analysis according to claim 8, wherein
said step of calculating electromagnetic field includes the steps of calculating electromagnetic field of up to n layers in the vicinity of the block in a first time step, calculating electromagnetic field of up to n−1 layers in the vicinity of the block in a second time step, repeating these processes to narrow the region of which electromagnetic field is to be calculated, and calculating electromagnetic field only in the block in the n-th step.
